(19) United States
(12) Patent Application Publication
(10) Pub. No.: US 2014/0369000 A1
(43) Pub. Date: Dec. 18, 2014

(54) TERMINAL UNIT

(71) Applicant: LG ELECTRONICS INC., Seoul (KR)

(72) Inventors: Injoong Kim, Seoul (KR); Joungwook Park, Seoul (KR)

(21) Appl. No.: 14/375,606

(22) PCT Filed: Jun. 20, 2013
(86) PCT No.: PCT/KR2013/005465

§ 371 Date: Jul. 30, 2014

(30) Foreign Application Priority Data
Jun. 20, 2012 (KR) 10-2012-0065898

(51) Int. Cl. H05K 7/20

(52) U.S. Cl. CPC H05K 7/2039
USPC 361/689; 361/713

(57) ABSTRACT

A terminal unit according to an embodiment of the present invention includes: a case forming the outer shape; and a frame disposed in the case and having a heat dissipation channel, in which the frame includes: a first panel made of a material having high thermal conductivity and disposed in the case; and a second panel made of a material having a high insulating property and combined with the first panel.

### TECHNICAL FIELD

The present invention relates to a terminal unit.

### BACKGROUND ART

Terminal units can fall into a mobile/portable terminal unit and a stationary terminal unit, depending on whether they can be moved. The mobile/portable terminal unit can fall into a hand-held terminal unit and a cradle-typed terminal unit, depending on whether a user can carry them in person.

Those terminal units are implemented in multimedia players with a composite function such as taking pictures or videos, playing music or video files, and receiving games and broadcasting, as the function is varied.

The outer shape of the terminal units is formed by combining a front case with a rear case and a frame may be further provided between the front case and the rear case. Various electronic components, including a printed circuit board for the function of the terminal units, may be disposed between the front case and the rear case.

Most of the electronic components are operated by power from a battery in the terminal units and generate high-temperature heat. In particular, a PAM (Power Amplifier Module), which amplifies an electric wave signal generated by operating the key pads on the terminal units to a predetermined level, before the signals are transmitted to the outside through an antenna, generates high-temperature heat in operation and the heat is transmitted to the terminal case, such that a user feels hot. In this case, the user may be in danger of getting burned at a low temperature, in addition to feeling unpleasant when using the terminal units. Further, when the high-temperature heat keeps generated, the electronic components on the printed circuit board cannot display their functions due to deterioration.

In the related art, a heat dissipation sheet is attached to the frame in order to dissipate the heat generated by the electronic components. However, the frame has a plurality of holes, grooves, and protrusions to mount various electronic devices for the terminal units, and thus it was difficult to attach the heat dissipation sheet. Further, the frame was etched in some cases to make a space for seating the electronic components, but there was a problem in this case that the heat dissipation sheet may be damaged.

Further, since the heat dissipation sheet is bonded like a sticker, the heat dissipation effect may be reduced by half by the bonding side of the heat dissipation sheet and a protective layer such as PET and a defect is likely to be cause in the product, for example bubbles generated between the frame and the heat dissipation sheet in the process of attaching the heat dissipation sheet to the frame or attachment of the heat dissipation sheet to a wrong position.

### DISCLOSURE OF INVENTION

### Technical Problem

An object of the present invention is to uniformly distribute heat, which is generated at a specific portion in a terminal unit, throughout the terminal unit, by preventing vertical heat transfer and allowing horizontal heat transfer.

In order to achieve the object of the present invention, a terminal unit according to an embodiment of the present invention includes: a case forming the outer shape; and a frame disposed in the case and having a heat dissipation channel, in which the frame includes: a first panel made of a material having high thermal conductivity and disposed in the case; and a second panel made of a material having a high insulating property and combined with the first panel.

### Solution to Problem

According to an embodiment of the present invention, it is possible to prevent heat generated at a specific portion in a terminal unit from being transmitted to a user, to prevent the terminal unit from being locally heated, and to uniformly distribute the heat generated at a specific portion in the terminal unit throughout the terminal unit.

Therefore, it is possible to prevent a user from feeling unpleasant when the user uses the terminal unit and to prevent an error due to damage to the components of the terminal unit by high temperature, such that it is possible to improve reliability of the quality of the terminal unit.

### BRIEF DESCRIPTION OF DRAWINGS

FIG. 1 is a perspective view showing a terminal unit according to an embodiment of the present invention.

FIG. 2 is an exploded perspective view showing the terminal unit according to an embodiment of the present invention.

FIG. 3 is a cross-sectional view taken along line A-A′in FIG. 2 in accordance with an embodiment of the present invention.

FIG. 4 is a cross-sectional view taken along line A-A′ in FIG. 2 in accordance with another embodiment of the present invention.

FIG. 5 is a cross-sectional view taken along line B-B′ in FIG. 2 in accordance with another embodiment of the present invention.

FIG. 6 is a view showing a first panel according to a first embodiment of the present invention.

FIG. 7 is a view showing a first panel according to a second embodiment of the present invention.

FIG. 8 is a view showing a first panel according to a third embodiment of the present invention.

### BEST MODE FOR CARRYING OUT THE INVENTION

Hereinafter, a terminal of the present invention will be described in detail with reference to the drawings. The suffixes “module and “unit used for the components in the following description are provided or used in consideration of only convenience of describing the specification and they do not have differentiated meanings or functions by themselves.

The terminal unit described herein may include not only mobile/portable terminal units such as a smart phone, a laptop computer, a digital broadcasting terminal unit, a PDA (Personal Digital Assistant), a PMP (Portable Multimedia Player), and a navigation device, but stationary terminal units such as a digital TV and a desktop computer.

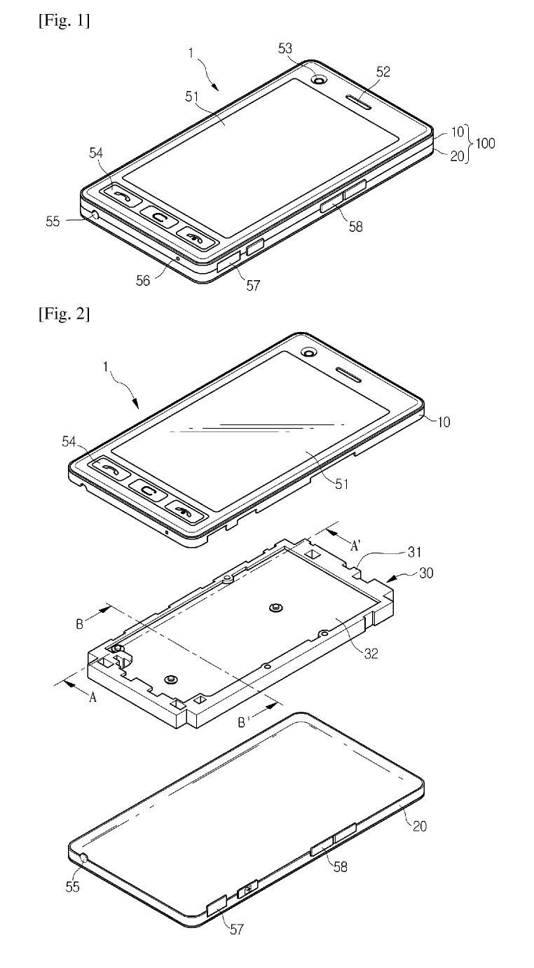

FIG. 1 is a perspective view showing a terminal unit according to an embodiment of the present invention and FIG. 2 is an exploded perspective view showing the terminal unit according to an embodiment of the present invention.

Referring to FIGS. 1 and 2, a terminal unit 1 according to an embodiment of the present invention is a bar-typed terminal unit. The present invention, however, is not limited to the bar-typed terminal unit and may be available for various structures such as a slid type, a folder type, a swing type, and a swivel type.

The terminal unit 1 includes a case 100 forming the outer shape. The case 100 includes a front case 10 that is the front part of the terminal unit and a rear case 20 that is the rear part of the terminal unit. A battery case (not shown) may be further disposed on the rear side of the rear case 20. The battery case is separably mounted on the rear case 20. A user can replace a battery in the rear case 20 after separating the battery case (not shown).

A frame 30 on which a PCB circuit etc. may be seated may be disposed between the front case 10 and the rear case 20. Various electronic components, including a printed circuit board, may be disposed in the space formed between the front case 10 and the rear case 20. The case 100 or the frame 30 may be formed by injection-molding synthetic resin or may be made of a metallic material such as stainless steel (STS) or titanium Ti.

The frame 30 may include an injection-molded frame 31 and a panel 32. The injection-molded frame 31 may be formed by injection-molding a material containing synthetic resin, at the edge of the panel 32. Various electronic components may be mounted on the panel 32 and the injection-molded frame 31 may have fitting portions for coupling to the front case 10 or the rear case 20. The structure of the panel will be described below.

In a terminal unit body formed by the front case 10 and the rear case 20, a display unit 51, a sound output unit 52, a recording unit 53, user input units 54, and 58, an antenna 55, a microphone 56, and an interface 57 may be provided.

The display unit 51 occupies most of the main side of the front case 10. The sound output unit 52 and the recording unit 53 may be disposed in the area close to one of both ends of the display unit 51 and the user input unit 54, the antenna 55, and the microphone 56 may be disposed in the area close to the other end.

The structure of the panel 32 of the frame 30 is described hereafter.

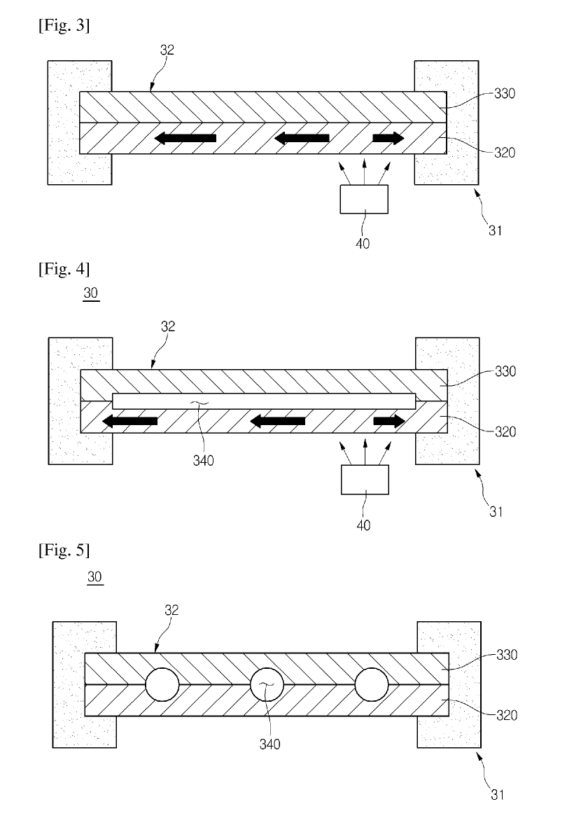

FIG. 3 is a longitudinal cross-sectional view of the terminal unit according to an embodiment of the present invention, taken along line A-A in FIG. 2.

Referring to FIG. 3, the frame 30 includes the injection-molded frame 31 and the panel 32. The panel includes a first panel 320 and a second panel 330. The first panel 320 may be made of a material having high thermal conductivity and the second panel 330 may be made of a material having a high insulating property. The rear case 20 may be disposed under the first panel 320 and the front case 10 may be disposed over the second panel 330. The arrangement of the first panel 320 and the second panel 330 is not limited thereto, but it is assumed in the following description that the rear case 20 is disposed under the first panel 320 and the front case 10 is disposed over the second panel 330.

The injection-molded frame 31 may be formed by injection molding on the edges of the first panel 320 and the second panel 330. For example, the injection-molded frame 31 may be formed by injection-molding a material containing synthetic resin such as plastic. The injection-molded frame 31 may have fitting portions such as fitting grooves through which fasteners for combining the frame 30 with the front case 10 or the frame 30 with the rear case 20 can be inserted.

The first panel 320 may be made of a material having high thermal conductivity. The first panel 320 may be made of a metallic material having high thermal conductivity which contains copper Cu, aluminum Al, and silver Ag. Am electronic components generating high-temperature heat is disposed under the first panel 320. The electronic component generating high-temperature heat may be referred to as a heat-generating device 40 hereafter. The heat-generating device 40 may be a semiconductor on the printed circuit board (not shown). The first panel 320 may be arranged opposite the heat-generating device 40. The first panel 320 may be disposed in close contact with the heat-generating device 40, with a heat transfer pad or a heat transfer member therebetween.

Heat generated by the heat-generating device 40 may be transmitted to the first panel 320 and the first panel 320 may be locally heated by the heat-generating device 40. When the first panel 320 is made of a metallic material having high thermal conductivity, the heat locally transmitted to the first panel 320 may quickly diffuse throughout the first panel 320. Accordingly, the difference between the maximum temperature and the minimum temperature of the first panel 320 is minimized and the temperature of the first panel 320 may be maintained as uniformly as possible throughout the area.

The first panel 330 may be made of a material having high heat resistance and adiabaticity. The components for the display unit 51 etc. may be mounted on the second panel 330, such that the second panel 330 may be made of a material that is strong enough to stably hold the components. Further, since the second panel 330 is combined with the first panel 320, it may be made of a material having a coefficient of linear expansion similar to that of the first panel 320. As the first panel 320 and the second panel 330 are made of materials having similar coefficients of linear expansion, the first panel 320 and the second panel 330 can be prevented from separating or deforming due to the heat from the heat-generating device 40.

For example, the second panel may be made of a material such as engineering plastic having high heat resistance or super engineering plastic having higher heat resistance than the engineering plastic. The engineering plastic means a plastic material generally having high heat resistance of 100 C or more and high strength and the super engineering plastic means a material having heat resistance of 150 C or more. The engineering plastic has high heat resistance and insulating property and has a coefficient of linear expansion similar to metal for making the first panel 320, such as copper Cu, such that it may be a suitable material for the second panel 330. The material of the second panel 330 is not limited to that described above an may be any one as long as it has high heat resistance and insulating property and has a coefficient of linear expansion similar to the first panel 320.

The second panel 330 may be rolled, attached by an adhesive, fastened by fasteners, or combined by welding, to the first panel 320. The way of combining the second panel 330 with the first panel 320 is not limited to those described above.

FIG. 4 is a longitudinal cross-sectional view of a terminal unit according to another embodiment of the present invention, taken along line A-A in FIG. 2 and FIG. 5 is a longitudinal cross-sectional view of a terminal unit according to another embodiment of the present invention, taken along line B-B′ in FIG. 2.

Referring to FIGS. 4 and 5, a channel 340 is formed between the first panel 320 and the second pane 330 and fluid for heat dissipation may be injected into the channel 340. The channel 340 may be formed by forming a groove on the first panel 320 or the second panel 330 and then combining the first panel 320 and the second panel 330 together.

The fluid may be liquid having large specific heat to be able to absorb heat well. For example, the fluid may be any one of water, alcohol, and acetone. The heat from the heat-generating device 40 is transmitted locally to the first panel 320 and the fluid receives the heat transmitted to the first panel 320 and flows in the channel 340. Since the fluid flows with latent heat in the channel 340, it can uniformly transmit heat to the first panel 320. The heat locally transmitted to the first panel 320 can be more quickly transmitted throughout the first panel 320 by the flowing of the fluid.

The channel 340 may be formed throughout the center portions of the first panel 320 and the second panel 330, as shown in FIG. 4. The channel 340 may be implemented by a plurality of long holes arranged at regular intervals between the first panel 320 and the second panel 330, as shown in FIG. 5. Alternatively, the channel 340 may extend in an S-shape.

Since the second panel 330 is made of a material having a high insulating property, the latent heat of the fluid is not transmitted to the second panel 330. Accordingly, the heat from the heat-generating device 40 is transmitted only horizontally and can be prevented from being vertically transmitted. That is, the heat from the heat-generating device 40 is not transmitted to the display unit or the front frame over the second panel 330.

Although it was described above that the channel 340 is formed between the first panel 320 and the second panel 330, the channel 340 may be formed only inside the first panel 320.

A method of manufacturing the frame 30 with the channel 340 is described hereafter.

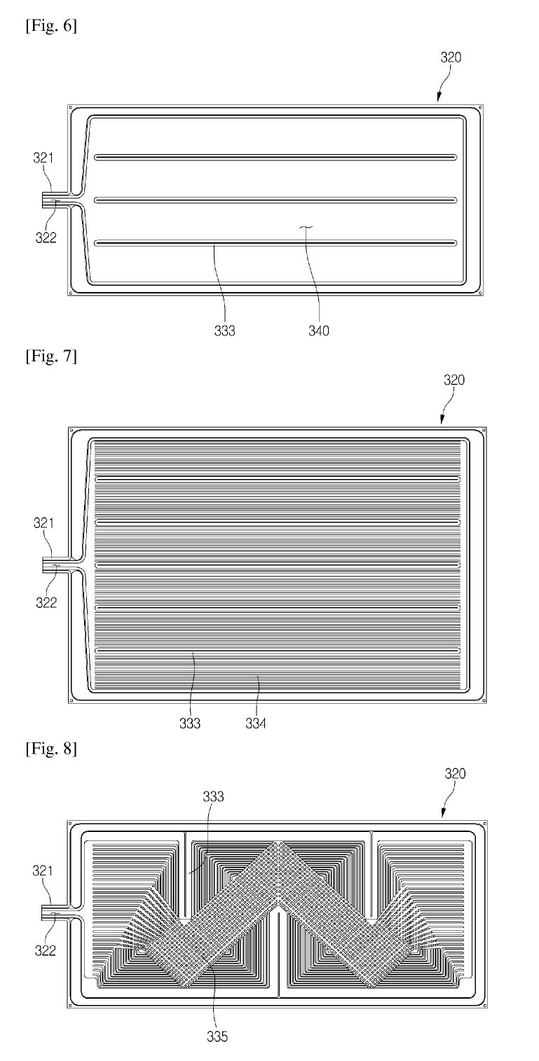

FIG. 6 is a view showing a first panel according to a first embodiment of the present invention.

Referring to FIG. 6, the channel 340 is formed on one side of the first panel 320 of the frame 30 according to a first embodiment. The channel 340 may be formed by a recession on one side of the first panel 320. The recession may be formed by etching the surface of the first panel 320. The groove may be implemented by forming a plurality of straight lines across the first panel 320.

The channel 304 may be formed throughout the first panel 320 so that the fluid flowing in the channel 340 can transmit heat throughout the first panel 320.

Although it was described above that the channel 340 is formed in the first panel 320, the channel 340 may be formed on one side of any one of the first panel 320 and the second panel 330 or opposite sides of them.

For example, a groove for the channel 340 may be formed on one side of the first panel 320 and a groove corresponding to the groove may be formed on one side of the second panel 330 too, at the position corresponding to the groove of the first panel. When the first panel 320 and the second panel 330 are combined, the groove on the first panel 320 and the groove on the second panel 330 vertically correspond to each other, such that a pipe-shaped channel can be achieved.

Ribs 333 for the channel 340 may protrude from one side of the first panel 320. The ribs 33 may come in contact with one side of the second panel 330. For example, an adhesive or an adhesive tape may be provided on the ribs 333, such that the ribs 333 may be bonded to one side of the second panel 330 when the first panel 320 and the second panel 330 are combined. Therefore, the first panel 320 and the second panel 330 may be more firmly combined.

A protrusion 321 may be disposed at one side of the first panel 320 or the second panel 330 and a hole 322 may be formed at the protrusion 321 so that fluid can be injected into the channel 340. The hole 322 is connected with the channel 340. Fluid is injected through the hole 322, after the first panel 320 and the second panel 330 are combined. After the fluid is injected, the protrusion 321 is cut off and the portion where the hole 322 is formed on the first panel 320 is closed by welding etc. Accordingly, the frame 30 with fluid in the channel 340 can be achieved.

FIG. 7 is a view showing a first panel according to a second embodiment of the present invention.

Referring to FIG. 7, wicks 334 that induces capillary action may be formed in the channel 340 on the first channel 320, for smooth flow of the fluid along the channel 340. Since the wicks 334 are formed, the fluid can more smoothly flow along the channel 340 by the capillary action. The wicks 334 may be formed partially or throughout along the channel 340.

Further, since the wicks 334 are formed in the channel 340, the heat transfer area that the fluid comes in contact with increases, thereby increasing the heat transfer speed.

When the heat-generating device 40 under the first panel 320 generates heat and the heat is transmitted locally to the first panel 320, the fluid can be quickly moved along the channel 340 by the wicks and uniformly transmitted throughout the first panel 320.

FIG. 8 is a view showing a first panel according to a third embodiment of the present invention.

Referring to FIG. 8, the channel 340 on the first panel 320 may be implemented in various ways. The channel 340 may be implemented by straight lines formed across the first panel 320, as shown in FIGS. 6 and 7, or may be implemented in an irregular shape, as shown in FIG. 8. The channel 340 may be formed such that the first panel 320 can efficiently transmit the heat from the heat-generating device 40 throughout the first panel 320, in accordance with the position of the heat-generating device 40.

It was described above that the channel 340 or the wicks 333 are formed on the first panel 320, the channel 340 or the wicks 333 may be formed on at least any one of the first panel 320 and the second panel 330.

It was described that the channel 340 is provided at the frame 30, the channel 340 may be formed at another member close to the heat-generating device 40 to prevent the terminal unit 1 from being locally heated. For example, the channel 340 may be formed at the front case 10 or the rear case 20.

As the channel 340 filled with fluid is formed in the frame 30, the heat generated by the heat-generating device 40 can be quickly transmitted throughout the first panel 320. Since the first panel 320 is made of a material having high thermal conductivity, it can quickly receive the heat transmitted from the fluid flowing along the channel 340. Therefore, the heat from the heat-generating device 40 can be uniformly transmitted to the first panel 320 and local heating of the frame 30 can be minimized.

Further, since the second panel 330 is made of a material having a high insulating property, it is possible to minimize the heat transmitted upward to the second panel 330 from the fluid or the first panel 320. Therefore, it is possible to prevent a user from feeling unpleasant due to the heat, when the user uses the terminal unit.

1. A terminal unit comprising:
a case forming the outer shape; and
a frame disposed in the case and having a heat dissipation channel,
wherein the frame includes:
a first panel made of a material having high thermal conductivity and disposed in the case; and
a second panel made of a material having a high insulating property and combined with the first panel.

2. The terminal unit of claim 1, wherein fluid having specific heat is injected into the heat dissipation channel.

3. The terminal unit of claim 2, wherein a portion of the heat dissipation channel is formed by recessions on the sides facing each other of the first panel and the second panel, and
the heat dissipation channel is achieved by close contact of the first panel and the second panel.

4. The terminal unit of claim 2, wherein the heat dissipation channel is formed on one side of any one of the first panel and the second panel.

5. The terminal unit of claim 2, wherein a plurality of wicks is formed on the inner sides of the heat dissipation channel.

6. The terminal unit of claim 1, wherein the first panel is made of a metallic material and the second panel is made of engineering plastic.

7. The terminal unit of claim 6, wherein the first panel is made of a metallic material containing at least one of copper, silver, and aluminum.

8. The terminal unit of claim 1, wherein a heat-generating device is disposed at the lower portion of the frame and the first panel is disposed opposite the heat-generating device.

9. The terminal unit of claim 1, wherein the first panel and the second panel have the same of similar coefficient of linear expansion.

10. The terminal unit of claim 1, wherein the heat dissipation channel is implemented by a plurality of long holes arranged at regular intervals.

11. The terminal unit of claim 1, wherein the heat dissipation channel extends in an S-shape.

12. The terminal unit of claim 1, wherein ribs protrude and extend at the edge of the heat dissipation channel.
